(19) United States
(12) Patent Application Publication
(10) Pub. No.: US 2013/0241648 A1
(43) Pub. Date: Sep. 19, 2013

(54) DRIVING CIRCUIT, OPERATIONAL AMPLIFIER, AND DATA TRANSMITTING METHOD THEREOF

(71) Applicant: RAYDIUM SEMICONDUCTOR CORPORATION, Hsinchu (TW)

(72) Inventors: Yu-Lung Lo, Taipei City (TW); Kuan-Hung Chou, Kaohsiung City (TW); Chih-Hsien Jen, Hsinchu City (TW)

(73) Assignee: Raydium Semiconductor Corporation, Hsinchu (TW)

(21) Appl. No.: 13/797,413

(22) Filed: Mar. 12, 2013

(30) Foreign Application Priority Data
Mar. 13, 2012 (TW) 101108490

(51) Int. Cl. H03F 3/45; H03K 17/06

(52) U.S. Cl. CPC H03F 3/45179; H03K 17/06
USPC 330/253; 327/108

(57) ABSTRACT

A data transmitting method is provided, wherein an operational amplifier is coupled with a channel and includes a positive switch, a negative switch, and a coupling end; the positive switch includes a positive control unit and a positive switch unit; the negative switch includes a negative control unit and a negative switch unit. The data transmitting method includes: transmitting an analog data to a first node and a second node from the coupling end; and by the positive control unit and the negative control unit, respectively according to a positive control signal and a negative control signal, selectively activating or deactivating the positive switch unit and the negative switch unit to control transmission of the analog data to an output end, wherein the output end is coupled between the negative switch unit and the positive switch unit.

### BACKGROUND OF THE INVENTION

1. Field of the Invention

The present invention relates generally to a driving circuit, an operational amplifier, and a data transmitting method; particularly, the present invention relates to a driving circuit, an operational amplifier, and a data transmitting method used in a display device.

2. Description of the Related Art

In general, the conventional display device includes a front-end circuit and a back-end circuit, wherein the front-end circuit processes digital data, and the back-end circuit converts the digital data into analog data and transmits the analog data to the panel to display images. Generally, the operation voltage range of the digital data is between 2.5 V and 3.5 V, which is low voltage. However, the operation voltage range of the analog data is between 0 V and 15 V, which is high voltage. In practical applications, the conventional display device utilizes the back-end circuit to convert the digital data.

Please refer to FIG. 1A; FIG. 1A is a schematic view of the back-end circuit of the conventional LCD device. As shown in FIG. 1A, a back-end circuit 111 includes a low voltage switch 11A, a digital/analog conversion module 12, an operational amplifier 13, a high voltage switch 11B, a first channel CH1, and a second channel CH2, wherein the digital/analog conversion module 12 includes a negative conversion unit 12A and a positive conversion unit 12B which are respectively disposed in the first channel CH1 and the second channel CH2.

It is noted that the operation voltage range of the first digital data D1 and the second digital data D2 is around 3V to 3.3 V, and the first digital data D1 and the second digital data D2 are respectively transmitted in the first channel CH1 and the second channel CH2. In practical applications, the first digital data D1 and the second digital data D2 are respectively transmitted to the digital/analog conversion module 12 by the low voltage switch 11A, and the negative conversion unit 12A and the positive conversion unit 12B respectively convert the first digital data D1 and the second digital data D2 into the first negative analog data D11 and the second positive analog data D22. The operational amplifier 13 respectively operates the first negative analog data D11 and the second positive analog data D22 in the first channel CH1 and the second channel CH2 and outputs the operated data to the high voltage switch 11B.

Please refer to FIG. 1B; FIG. 1B is a schematic view of the back-end circuit of the conventional LCD device. As shown in FIG. 1B, the first digital data D1 and the second digital data D2 are respectively transmitted in the first channel CH1 and the second channel CH2 and are switched to the second channel CH2 and the first channel CH1 by the low voltage switch 11A. In addition, the second digital data D2 and the first digital data D1 are converted into the second negative analog data D21 and the first positive analog data D12 by the negative conversion unit 12A and the positive conversion unit 12B. It is noted that the second negative analog data D21 and the first positive analog data D12 are respectively transmitted to the operational amplifier 13 for operation. The operated second negative analog data D21 and first positive analog data D12 are respectively transmitted to the high voltage switch 11B. It is noted that the second negative analog data D21 and the first positive analog data D12 are respectively switched to the second channel CH2 and the first channel CH1 by the high voltage switch 11B.

As shown in FIGS. 1A and 1B, the end of the first channel CH1 has a first negative analog data D11 and a first positive analog data D12, and the end of the second channel CH2 has a second positive analog data D22 and a second negative analog data D21, so that the first channel CH1 and the second channel CH2 can operate the analog data.

In practical applications, when researchers and developers design the back-end circuit 10, the low voltage switch 11A and the high voltage switch 11B have to be disposed in each channel to transmit the digital data or the analog data to the assigned channel. Particularly, the conventional display device utilizes the low voltage switch 11A and the high voltage switch 11B to switch the data respectively, so that each channel can operate corresponding positive analog data and negative analog data. It is desired to decrease the volume and the area of the conventional display device to produce small-size products. However, the low voltage switch 11A and the high voltage switch 11B have fixed volumes; it is hard to decrease the volume of the device effectively.

### SUMMARY OF THE INVENTION

In view of prior arts, the present invention provides a driving circuit, an operational amplifier, and a data transmitting method, which can effectively decrease the cost and the volume.

It is an object of the present invention to provide an operational amplifier, which compares the voltages and has high impedance.

It is an object of the present invention to provide a driving circuit, which decreases the amount of the voltage switches to decrease the cost of materials.

It is an object of the present invention to provide a data transmitting method, which utilizes control signals to control the analog data.

According to an embodiment of the present invention, an operational amplifier is provided, wherein the operational amplifier is connected to a channel. The operational amplifier includes a coupling end, a positive switch, a negative switch, and an output end, wherein the coupling end coupled with a first node and a second node, and an analog data is transmitted from the coupling end to the first node and the second node. The positive switch includes a positive control unit and a positive switch unit, and the first node is coupled with the coupling end and the positive switch unit, wherein the positive control unit is connected to the first node. In addition, the negative switch includes a negative control unit and a negative switch unit, wherein the second node is coupled with the coupling end and the negative switch unit, and the negative control unit is connected to the second node. The output end is coupled between the negative switch unit and the positive switch unit. The positive control unit and the negative control unit, respectively according to a positive control signal and a negative control signal, selectively activate or deactivate the positive switch unit and the negative switch unit to control transmission of the analog data to the output end.

According to another embodiment of the present invention, a driving circuit is provided. The driving circuit includes a plurality of channels and a plurality of operational amplifiers, wherein one of the operational amplifiers is coupled with one of the channels. The operational amplifier includes a coupling end, a positive switch, a negative switch, and an output end, wherein the coupling end is coupled with a first node and a second node, and an analog data is transmitted from the coupling end to the first node and the second node. The positive switch includes a positive control unit and a positive switch unit, wherein the first node is coupled with the coupling end and the positive switch unit, and the positive control unit is connected to the first node. It is noted that the negative switch includes a negative control unit and a negative switch unit, the second node is coupled with the coupling end and the negative switch unit, and the negative control unit is connected to the second node. The output end is coupled between the negative switch unit and the positive switch unit, wherein the positive control unit and the negative control unit, respectively according to a positive control signal and a negative control signal, selectively activate or deactivate the positive switch unit and the negative switch unit to control transmission of the analog data to the output end.

According to another embodiment of the present invention, a data transmitting method is provided for an operational amplifier, wherein the operational amplifier is coupled with a channel and includes a positive switch, a negative switch, and a coupling end. The coupling end is coupled with a first node and a second node. The positive switch includes a positive control unit and a positive switch unit. The first node is coupled with the coupling end and the positive switch unit. The positive control unit is connected to the first node. The negative switch includes a negative control unit and a negative switch unit. The second node is coupled with the coupling end and the negative switch unit. The negative control unit is connected to the second node. The data transmitting method includes: transmitting an analog data to the first node and the second node from the coupling end; and by the positive control unit and the negative control unit, respectively according to a positive control signal and a negative control signal, selectively activating or deactivating the positive switch unit and the negative switch unit to control transmission of the analog data to an output end, wherein the output end is coupled between the negative switch unit and the positive switch unit.

Compared to prior arts, the driving circuit, the operational amplifier, and the data transmitting method of the present invention respectively control the positive control unit and the negative control unit of the operational amplifier according to the positive control signal and the negative control signal, so that the positive switch unit and the negative switch unit can control whether the analog data is transmitted to the output end or not, further achieving the effect of the conventional high voltage switch. Hence, the embodiments of the present invention only utilize operational amplifiers of different design to control the analog data, eliminating the use of high voltage switches of the conventional display device and further decreasing the cost and the area of the chip.

The detailed descriptions and the drawings thereof below provide further understanding about the advantage and the spirit of the present invention.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A is a schematic view of the back-end circuit of the conventional LCD device;

FIG. 1B is a schematic view of the back-end circuit of the conventional LCD device;

FIG. 2 is a schematic view of the embodiment of an operational amplifier of the present invention;

FIG. 3 is a schematic view of another embodiment of the operational amplifier of the present invention;

FIG. 4 is a schematic view of the embodiment of the driving circuit of the present invention;

FIG. 5 is a flow chart of a data transmitting method of the present invention; and

FIG. 6 is a flow chart of the data transmitting method of the present invention.

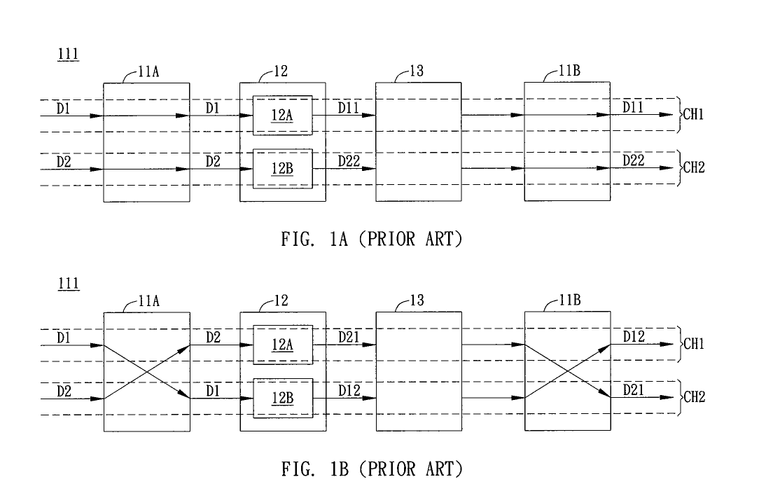

### DETAILED DESCRIPTION

According to an embodiment of the present invention, an operational amplifier is provided. In the embodiment, the operational amplifier is used in a driving circuit, especially a source driver circuit of an LCD device, but is not limited to the embodiment.

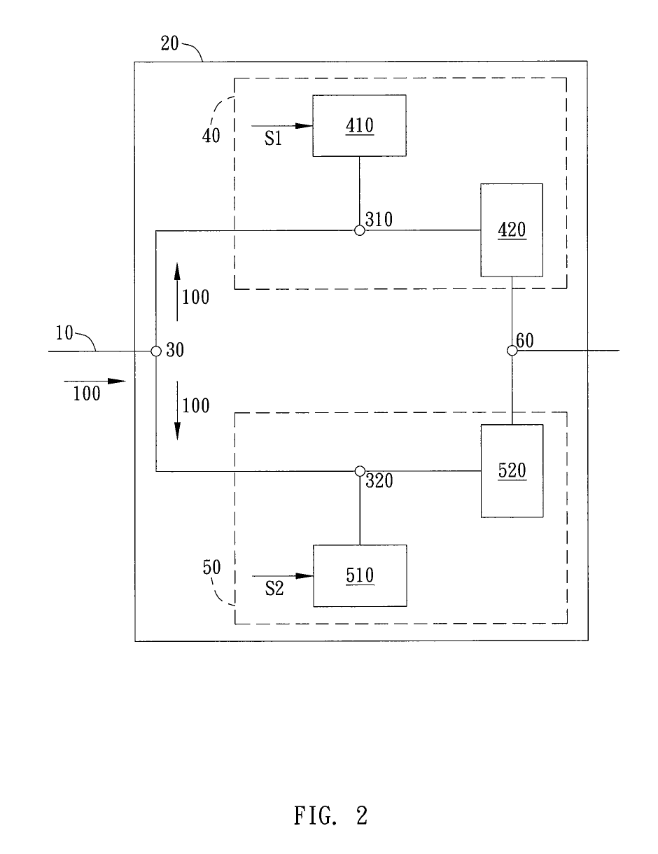

Please refer to FIG. 2; FIG. 2 is a schematic view of the embodiment of an operational amplifier of the present invention. As shown in FIG. 2, an operational amplifier 20 is connected to a channel 10 and includes a coupling end 30, a positive switch 40, a negative switch 50, and an output end 60, wherein the coupling end 30 is coupled with a first node 310 and a second node 320. It is noted that the channel 10 can be any type of circuit channel and not limited to the embodiment. In the embodiment, the difference between the positive switch 40 and the negative switch 50 is amplitude of the working voltage. For instance, the voltage of the positive switch 40 approaches the operating voltage of the operational amplifier, and the voltage of the negative switch 50 approaches zero potential. However, in other embodiments, the voltage of the positive switch 40 and the negative switch 50 can be controlled by the driving circuit, but not limited to the embodiment.

It is noted that the positive switch 40 includes a positive control unit 410 and a positive switch unit 420, wherein the first node 310 is coupled with the coupling end 30 and the positive switch unit 420, and the positive control unit 410 is connected to the first node 310. In addition, the negative switch 50 includes a negative control unit 510 and a negative switch unit 520, wherein the second node 320 is coupled with the coupling end 30 and the negative switch unit 520, and the negative control unit 510 is connected to the second node 320.

It is noted that the output end 60 is coupled between the negative switch unit 520 and the positive switch unit 420, wherein the positive control unit 410 and the negative control unit 420, respectively according to a positive control signal S1 and a negative control signal S2, selectively activate or deactivate the positive switch unit 420 and the negative switch unit 520 to control transmission of the analog data 100 to the output end 60.

Particularly, the present invention utilizes the positive control signal S1 and the negative control signal S2 to respectively control the positive control unit 410 and the negative control unit 420, and the positive control unit 410 and the negative control unit 420 respectively output an operated result, so that the positive switch unit 420 and the negative switch unit 520 is driven to be activated or to be deactivated according to the operated result, further determining whether the analog data is transmitted to the output end or not. In other words, the positive control unit 410 and the negative control unit 510 can be any type of control logic circuit, and the positive switch unit 420 and the negative switch unit 520 can be any type of switch component. For instance, the positive control unit 410A, the positive switch unit 420A, the negative control unit 510A, and the negative switch unit 520A can be transistors or other circuit components, not limited to the embodiment.

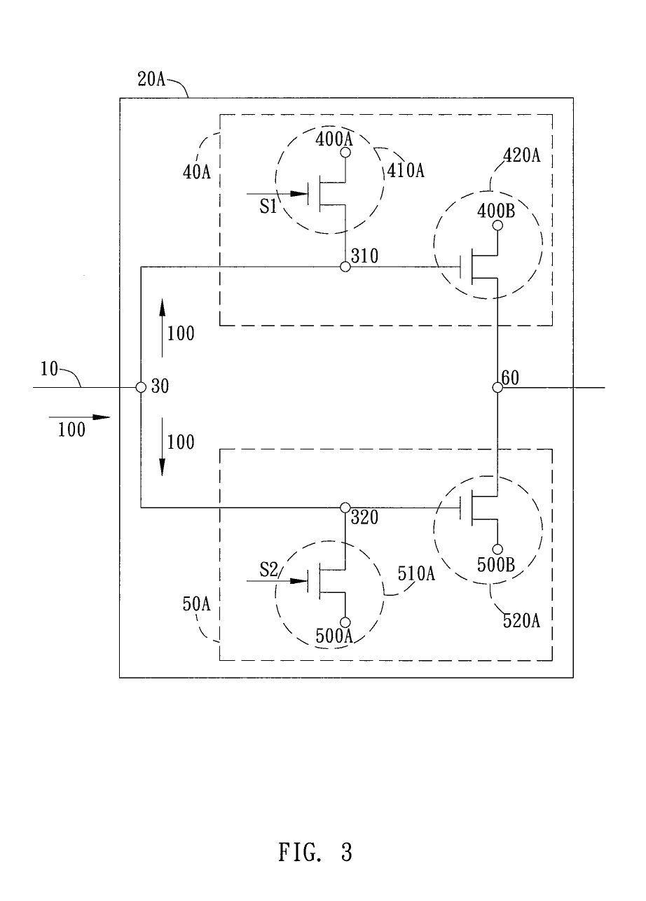

Please refer to FIG. 3; FIG. 3 is a schematic view of another embodiment of the operational amplifier of the present invention. As shown in FIG. 3, the operational amplifier 20A includes the positive switch 40A and the negative switch 40B. The positive switch 40A has a positive control unit 410A and a positive switch unit 420A. The negative switch 50A has a negative control unit 510A and the negative switch unit 520A. In the embodiment, the positive control unit 410A, the positive switch unit 420A, the negative control unit 510A, and the negative switch unit 520A are transistors. The present invention utilizes the operating voltage of the positive control unit 410A and the negative control unit 510A and selectively outputs the voltage to the positive switch unit 420A and the negative switch unit 520A to control the transmission of the analog data, either for data transmission or stopping the data transmission.

In practical applications, the positive control unit 410A and the negative control unit 510A respectively output a positive control voltage 400A and a negative control voltage 500A to the positive switch unit 420A and the negative switch unit 520A according to the positive control signal S1 and the negative control signal S2. It is noted that the positive switch unit 420A and the negative switch unit 520A respectively have a positive switch voltage 400B corresponding to the positive control voltage 400A and a negative switch voltage 500B corresponding to the negative control voltage 500A, so that the positive switch unit 420A and the negative switch unit 520A are controlled to stop transmitting the analog data 100 to the output end 60.

It is noted that the operational amplifier 20A has the operating voltage. For instance, the range of the operating voltage can be between 0 V and 15 V, but not limited to the embodiment. In the embodiment, the operating voltages of the operational amplifier 20A, the positive control voltage 400A, and the positive switch voltage 400B are identical. In addition, the negative control voltage 500A and the negative switch voltage 500B are zero potential. In the embodiment, the negative control unit 510A and the negative switch unit 520A are connected to the ground, so that the negative control voltage 500A and the negative switch voltage 500B are zero potential.

In practical applications, the positive switch unit 420A utilizes the positive control voltage 400A and the positive switch voltage 400B, which are identical, as well as the negative control voltage 500A and the negative switch voltage 500B, which are identical, to generate open circuit between the positive switch unit 420A and the negative switch unit 520A. In other words, when the positive switch unit 420A and the negative switch unit 520A respectively receive the positive control voltage 400A and the negative control voltage 500A from the positive control unit 410A and the negative control unit 510A, the positive switch unit 420A and the negative switch unit 520A are at open circuit state, so that the transmission of the analog data 100 to the output end 60 is stopped.

Relatively, the positive control unit 410A and the negative control unit 510A stop outputting the positive control voltage 400A and the negative control voltage 500A to the positive switch unit 420A and the negative switch unit 520A according to the positive control signal S1 and the negative control signal S2, so that the positive switch unit 420A and the negative switch unit 520A are controlled to transmit the analog data 100 to the output end 60.

In other words, when the positive switch unit 420A and the negative switch unit 520A respectively stop receiving the positive control voltage 400A and the negative control voltage 500A from the positive control unit 410A and the negative control unit 510A, the positive switch unit 420A and the negative switch unit 520A are at conducting state, so that the analog data 100 is transmitted to the output end 60.

Hence, the operational amplifier 20A of the present invention utilizes the positive control signal S1 and the negative control signal S2 to control the positive switch 40A and the negative switch 50A to determine whether the analog data 100 is transmitted to the output end 60 or not.

According to another embodiment of the present invention, a driving circuit is provided. In the embodiment, the driving circuit is used in an LCD device to drive an LCD panel, but not limited to the embodiment. In other embodiments, the driving circuit can be used in any type of display device, such as plasma display devices, laser display devices, or other display devices, and not limited the embodiment. In practical applications, the driving circuit can be a source driver circuit of the display panel, but is not limited to the embodiment. In the embodiment, the front-end circuit of the display device has a plurality of even number channels and a plurality of odd number channels, wherein the even number channels and the odd number channels are connected with the source driver circuit of the display panel, so that digital data in the channels is switched by the source driver circuit and is converted into analog data. In other words, the driving circuit is the back-end circuit of the display panel and is used to output the analog data to the display panel to output images.

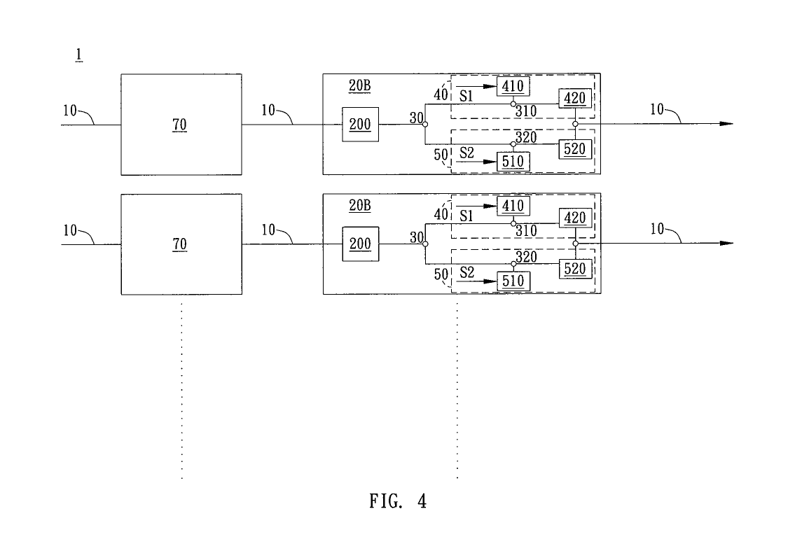

Please refer to FIG. 4; FIG. 4 is a schematic view of the embodiment of the driving circuit 1 of the present invention. As shown in FIG. 4, the driving circuit 1 includes a plurality of channels 10, a plurality of operational amplifiers 20B, and a plurality of digital/analog conversion modules. The operational amplifiers 20B are coupled with corresponding channels 10. Each digital/analog conversion module 70 is connected to the operational amplifier 20B by the channel 10, and the digital data is converted into the analog data by the digital/analog conversion module 70 and then transmitted to the operational amplifier 20B.

It is noted that the digital data and the analog data are transmitted in the driving circuit 1 in form of voltage, wherein a voltage of the digital data is between 2.5 V and 3.5 V; a voltage of the analog data is between 0 V and 15 V, but not limited to the embodiment. In other words, the digital/analog conversion module 70 converts the digital data into an analog data as an analog voltage. In practical applications, low voltage (e.g. 3 V) cannot drive the display panel, so the driving circuit 1 utilizes the analog voltage (e.g. 7.5 V) to drive the display panel. In the embodiment, the digital/analog conversion module 70 is a level shifter and can convert the voltage of the digital data, but not limited to the embodiment.

With regard to detailed descriptions of the circuit configuration of the operational amplifier 20B, in addition to the circuit components of the operational amplifier 20 in FIG. 2, an operating unit 200 is further included. In the embodiment, the operating unit 200 operates and amplifies the analog data, and transmits the analog data to the first node 310 and the second node 320 through the coupling end 30. In addition, the operational amplifier 20B controls the positive switch 40 and the negative switch 50 to transmit or to stop transmitting the analog data to the output end 60. In practical applications, the analog data is transmitted to the display panel to output images on the display panel.

In addition to the embodiment of the driving circuit 1, a data transmitting method of the present invention is provided to illustrate the practical operating steps.

According to another embodiment of the present invention, a data transmitting method is provided to illustrate steps of transmitting the analog data.

It is noted that the data transmitting method is used in an operational amplifier, wherein the operational amplifier is coupled with a channel and includes a positive switch, a negative switch, and a coupling end. The coupling end is coupled with a first node and a second node. The positive switch includes a positive control unit and a positive switch unit. The first node is coupled with the coupling end and the positive switch unit. The positive control unit is connected to the first node. The negative switch includes a negative control unit and a negative switch unit. The second node is coupled with the coupling end and the negative switch unit. The negative control unit is connected to the second node.

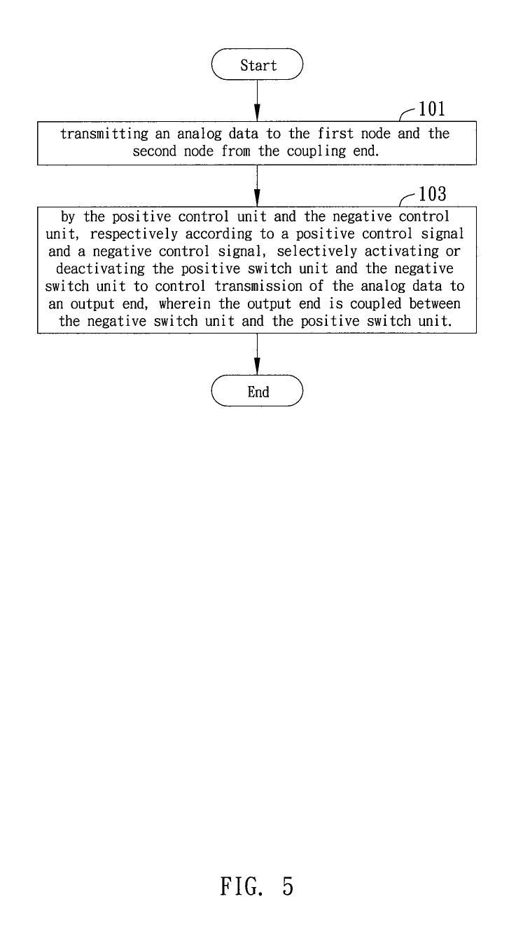

Please refer to FIG. 5; FIG. 5 is a flow chart of a data transmitting method of the present invention. Firstly, the data transmitting method executes the step 101: transmitting an analog data to the first node and the second node from the coupling end. For instance, as shown in FIG. 2, the analog data 100 is transmitted to the first node 310 and the second node 320 from the coupling end 30.

In addition, the data transmitting method executes the step 103: by the positive control unit and the negative control unit, respectively according to a positive control signal and a negative control signal, selectively activating or deactivating the positive switch unit and the negative switch unit to control transmission of the analog data to an output end, wherein the output end is coupled between the negative switch unit and the positive switch unit. As shown in FIG. 2, the positive control unit 410 and the negative control unit 510, respectively according to the positive control signal S1 and the negative control signal S2, selectively activate or deactivate the positive switch unit 420 and the negative switch unit 520 to control transmission of the analog data 100 to the output end 60.

In addition, in the flow chart of FIG. 5, the positive control unit and the negative control unit respectively have a positive control voltage and a negative control voltage. The positive switch unit and the negative switch unit respectively have a positive switch voltage corresponding to the positive control voltage and a negative switch voltage corresponding to the negative control voltage. In addition, the positive control voltage and the positive switch voltage are identical. The negative control voltage and the negative switch voltage are zero potential.

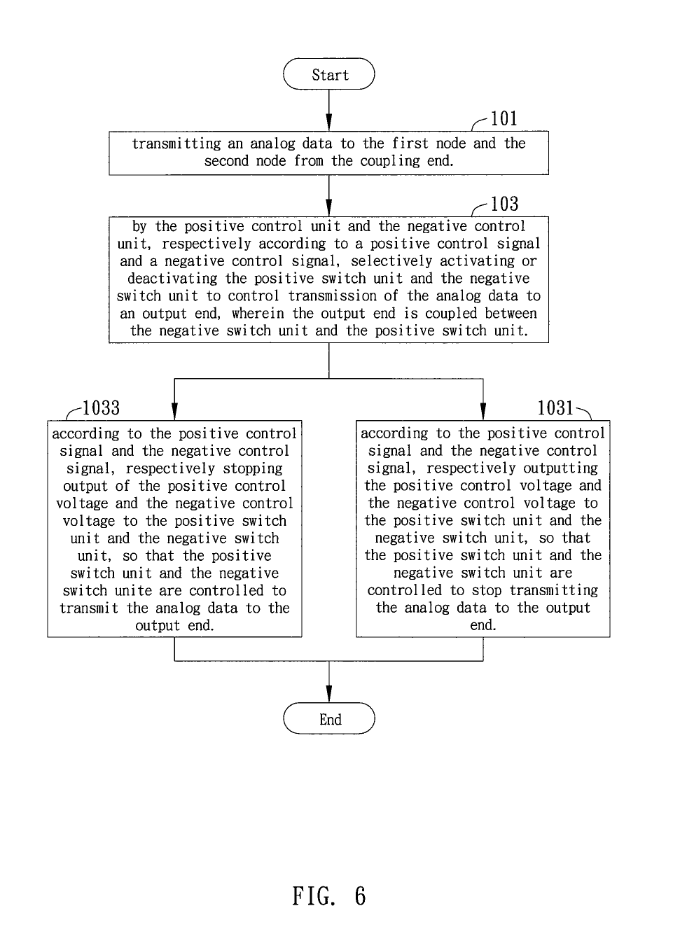

Please refer to FIG. 6; FIG. 6 is a flow chart of the data transmitting method of the present invention. The data transmitting method further executes the step 1031: according to the positive control signal and the negative control signal, respectively outputting the positive control voltage and the negative control voltage to the positive switch unit and the negative switch unit, so that the positive switch unit and the negative switch unit are controlled to stop transmitting the analog data to the output end. As shown in FIG. 3, the positive control unit 410A and the negative control unit 510A, according to the positive control signal S1 and the negative control signal S2, respectively output the positive control voltage 400A and the negative control voltage 500A to the positive switch unit 420A and the negative switch unit 520A, so that the positive switch unit 420A and the negative switch unit 520A are controlled to stop transmitting the analog data 100 to the output end 60.

The step 1033 includes, according to the positive control signal and the negative control signal, respectively stopping output of the positive control voltage and the negative control voltage to the positive switch unit and the negative switch unit, so that the positive switch unit and the negative switch unite are controlled to transmit the analog data to the output end. As shown in FIG. 3, the positive control unit 410A and the negative control unit 510A, according to the positive control signal S1 and the negative control signal S2, respectively stop output of the positive control voltage 400A and the negative control voltage 500A to the positive switch unit 420A and the negative switch unit 520A, so that the positive switch unit 420A and the negative switch unit 520A are controlled to transmit the analog data 100 to the output end 60.

Hence, the present invention utilizes the positive control signal S1, the negative control signal S2, the positive switch 40, and the negative switch 50 to control transmission of the analog data 100 rather than disposing the high voltage switch, further decreasing the cost of material and the area of the chip.

Compared to prior arts, the driving circuit, the operational amplifier, and the data transmitting method of the present invention respectively control the positive control unit and the negative control unit of the operational amplifier according to the positive control signal and the negative control signal, so that the positive switch unit and the negative switch unit can control whether the analog data is transmitted to the output end or not, achieving the effect of the conventional high voltage switch. Hence, the embodiments of the present invention only utilize operational amplifiers of different design to control the analog data, eliminating the use of high voltage switches of the conventional display device and further decreasing the cost and the area of the chip.

Although the preferred embodiments of the present invention have been described herein, the above description is merely illustrative. Further modification of the invention herein disclosed will occur to those skilled in the respective arts and all such modifications are deemed to be within the scope of the invention as defined by the appended claims.

1. A driving circuit, comprising:
a plurality of channels; and
a plurality of operational amplifiers, wherein one of the operational amplifiers is coupled with one of the channels and comprises:
a coupling end coupled with a first node and a second node, wherein an analog data is transmitted from the coupling end to the first node and the second node;
a positive switch comprising a positive control unit and a positive switch unit, wherein the first node is coupled with the coupling end and the positive switch unit, and the positive control unit is connected to the first node;
a negative switch comprising a negative control unit and a negative switch unit, wherein the second node is coupled with the coupling end and the negative switch unit, and the negative control unit is connected to the second node; and
an output end coupled between the negative switch unit and the positive switch unit, wherein the positive control unit and the negative control unit, respectively according to a positive control signal and a negative control signal, selectively activate or deactivate the positive switch unit and the negative switch unit to control transmission of the analog data to the output end.

2. The driving circuit of claim 1, wherein the positive control unit and the negative control unit respectively output a positive control voltage and a negative control voltage to the positive switch unit and the negative switch unit according to the positive control signal and the negative control signal, and the positive switch unit and the negative switch unit respectively have a positive switch voltage corresponding to the positive control voltage and a negative switch voltage corresponding to the negative control voltage, so that the positive switch unit and the negative switch unit are controlled to stop transmitting the analog data to the output end.

3. The driving circuit of claim 2, wherein the positive control unit and the negative control unit stop outputting the positive control voltage and the negative control voltage to the positive switch unit and the negative switch unit according to the positive control signal and the negative control signal, so that the positive switch unit and the negative switch unit are controlled to transmit the analog data to the output end.

4. The driving circuit of claim 2, wherein the positive control voltage and the positive switch voltage are identical.

5. The driving circuit of claim 2, wherein the negative control voltage and the negative switch voltage are zero potential.

6. An operational amplifier connected to a channel, the operational amplifier comprising:
a coupling end coupled with a first node and a second node, wherein an analog data is transmitted from the coupling end to the first node and the second node;
a positive switch comprising a positive control unit and a positive switch unit, wherein the first node is coupled with the coupling end and the positive switch unit, and the positive control unit is connected to the first node;
a negative switch comprising a negative control unit and a negative switch unit, wherein the second node is coupled with the coupling end and the negative switch unit, and the negative control unit is connected to the second node; and
an output end coupled between the negative switch unit and the positive switch unit, wherein the positive control unit and the negative control unit, respectively according to a positive control signal and a negative control signal, selectively activate or deactivate the positive switch unit and the negative switch unit to control transmission of the analog data transmitting to the output end.

7. The operational amplifier of claim 6, wherein the positive control unit and the negative control unit respectively output a positive control voltage and a negative control voltage to the positive switch unit and the negative switch unit according to the positive control signal and the negative control signal, and the positive switch unit and the negative switch unit respectively have a positive switch voltage corresponding to the positive control voltage and a negative switch voltage corresponding to the negative control voltage, so that the positive switch unit and the negative switch unit are controlled to stop transmitting the analog data to the output end.

8. The operational amplifier of claim 7, wherein the positive control unit and the negative control unit stop outputting the positive control voltage and the negative control voltage to the positive switch unit and the negative switch unit according to the positive control signal and the negative control signal, so that the positive switch unit and the negative switch unit are controlled to transmit the analog data to the output end.

9. The operational amplifier of claim 7, wherein the positive control voltage and the positive switch voltage are identical.

10. The operational amplifier of claim 7, wherein the negative control voltage and the negative switch voltage are zero potential.

11. A data transmitting method used in an operational amplifier, wherein the operational amplifier is coupled with a channel and comprises a positive switch, a negative switch, and a coupling end, the coupling end is coupled with a first node and a second node, the positive switch comprises a positive control unit and a positive switch unit, and the first node is coupled with the coupling end and the positive switch unit, the positive control unit is connected to the first node; the negative switch comprises a negative control unit and a negative switch unit, and the second node is coupled with the coupling end and the negative switch unit, the negative control unit is connected to the second node, the data transmitting method comprising:
(a) transmitting an analog data to the first node and the second node from the coupling end; and
(b) by the positive control unit and the negative control unit, respectively according to a positive control signal and a negative control signal, selectively activating or deactivating the positive switch unit and the negative switch unit to control transmission of the analog data to an output end, wherein the output end is coupled between the negative switch unit and the positive switch unit.

12. The data transmitting method of claim 11, wherein the positive control unit and the negative control unit respectively have a positive control voltage and a negative control voltage, and the positive switch unit and the negative switch unit respectively have a positive switch voltage corresponding to the positive control voltage and a negative switch voltage corresponding to the negative control voltage, the data transmitting method further comprises:
according to the positive control signal and the negative control signal, respectively outputting the positive control voltage and the negative control voltage to the positive switch unit and the negative switch unit, so that the positive switch unit and the negative switch unit are controlled to stop transmitting the analog data to the output end.

13. The data transmitting method of claim 12, further comprising:
according to the positive control signal and the negative control signal, respectively stopping output of the positive control voltage and the negative control voltage to the positive switch unit and the negative switch unit, so that the positive switch unit and the negative switch unit are controlled to transmit the analog data to the output end.

14. The data transmitting method of claim 12, wherein the positive control voltage and the positive switch voltage are identical.

15. The data transmitting method of claim 12, wherein the negative control voltage and the negative switch voltage are zero potential.
